(19) United States
(12) Patent Application Publication
(10) Pub. No.: US 2013/0043895 A1
(43) Pub. Date: Feb. 21, 2013

(54) FAN SPEED CONTROL DEVICE

(71) Applicant: ZI-YU ZHAN, Shenzhen City (CN)

(72) Inventor: ZI-YU ZHAN, Shenzhen City (CN)

(73) Assignees: HON HAI PRECISION INDUSTRY CO., LTD., Tu-Cheng (TW); HONG FU JIN PRECISION INDUSTRY (Shenzhen) CO., LTD., Shenzhen City (CN)

(21) Appl. No.: 13/347,085

(22) Filed: Jan. 10, 2012

(30) Foreign Application Priority Data
Aug. 17, 2011 (CN) 201110236010.1

(51) Int. Cl. G01R 31/34

(52) U.S. Cl. 324/750.01

(57) ABSTRACT

A fan speed control device is applied to a fan including a speed control signal port and a speed signal port. The fan speed control device includes a speed regulating circuit. The speed regulating circuit includes a signal control unit electrically connected to the speed signal port of the fan, and an adjustable resistor is electrically connected between the signal control unit and the speed control signal port of the fan. The resistance of the adjustable resistor may be varied to change the voltage and current supplied to the fan, and the rotational speed of the fan changes according to the operating voltage and current supplied. The signal control unit obtains speed signals from the speed signal port and processes and displays the current testing parameters of the fan.

### BACKGROUND

1. Technical Field

The disclosure generally relates to a fan speed control device for controlling rotational speed of fans.

2. Description of the Related Art

Computer cases and servers use fans for cooling purposes, so it is important to test the performance (e.g., rotational speed) of the fans. During testing, the rotational speed of the fan in the electronic device gradually reaches a reference value, if the computer fan and the electronic device are working normally (e.g., indicator light lights normally), which signifies the computer fan matches the electronic device. However, the rotational speed of the computer fan can not be adjusted in real-time during testing, which makes carrying out a test very difficult.

Therefore, there is room for improvement within the art.

### BRIEF DESCRIPTION OF THE DRAWINGS

Many aspects of a fan speed control device can be better understood with reference to the following drawings. The components in the drawings are not necessarily drawn to scale, the emphasis instead being placed upon clearly illustrating the principles of the fan speed control device. Moreover, in the drawings, like reference numerals designate corresponding parts throughout the several views. Wherever possible, the same reference numbers are used throughout the drawings to refer to the same or like elements of an embodiment.

FIG. 1 is a block view of one embodiment of a fan speed control device applied to a fan of the disclosure.

FIG. 2 is a schematic view of the fan speed control device shown in FIG. 1 of the disclosure.

### DETAILED DESCRIPTION

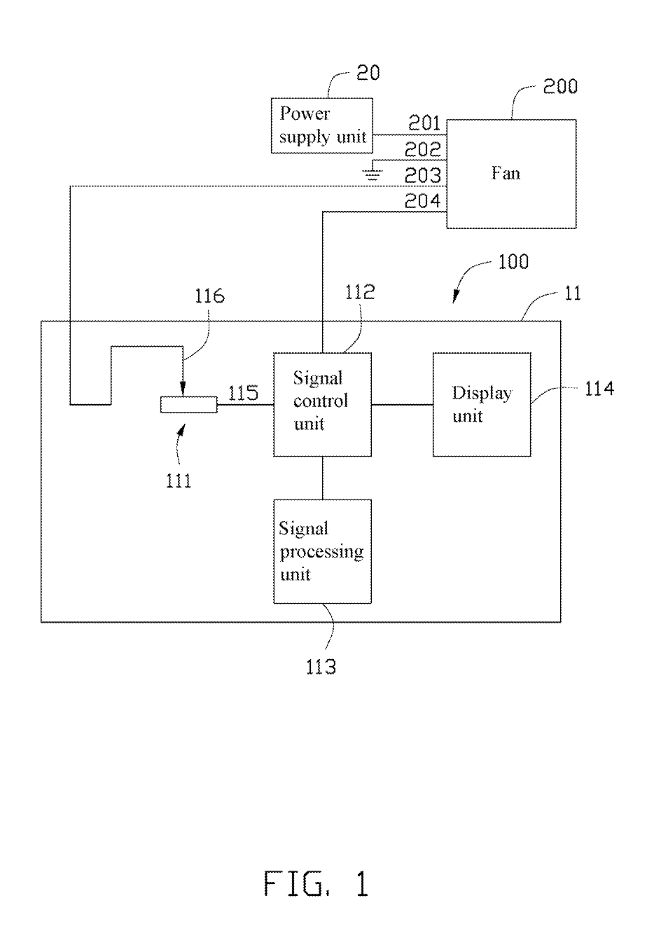

FIG. 1 is a block view of one embodiment of a fan speed control device 100 applied to a fan 200 of the disclosure. The fan speed control device 100 is used to control and adjust the rotational speed of the fan 200 to test the performance of the fan 200. The fan 200 can be a computer fan that is used for cooling purposes, and which draws cooler air into a computer from the outside, or expels warm air to the outside from the inside.

The fan 200 includes a power port 201, a ground port 202, a speed control signal port 203, and a speed signal port 204. The power port 201 is electrically connected to a power supply unit 20 for powering the fan 200. The ground port 202 is electrically connected to ground, and the speed control signal port 203 and the speed signal port 204 are electrically connected to the fan speed control device 100. The speed control signal port 203 can be electrically connected to a motor (not shown) of the fan 200. In this embodiment, the fan speed control device 100 includes a speed regulating circuit 11 electrically connected to the speed control signal port 203 and to the speed signal port 204.

The speed regulating circuit 11 includes an adjustable resistor 111, a signal control unit 112, a signal processing unit 113, and a display unit 114. The adjustable resistor 111 can be a potentiometer, variable resistor or rheostat that varies the resistance in the speed regulating circuit 11. The adjustable resistor 111 includes a fixed contact 115 and a sliding contact 116 that can be moved relative to the fixed contact 115. The fixed contact 115 is electrically connected to the signal control unit 112, and the sliding contact 116 is electrically connected to the speed control signal port 203 of the fan 200. Thus, by moving or adjusting the sliding contact 116, the resistance of the adjustable resistor 111 is variable so as to change operating voltage and current supplied to the fan 200, thus adjusting and changing the rotational speed of the fan 200.

The signal control unit 112 is electrically connected to the speed signal port 204, the fixed contact 115, the signal processing unit 113 and the display unit 114. The signal control unit 112 can receive signals as to the rotational speed from the speed signal port 204 as input and process the signals, to output the results of different operations performed in relation to the fan 200. For example, when the rotational speed of the fan 200 changes, the fan 200 sends the speed signal to the signal control unit 112 through the speed signal port 204, the signal control unit 112 processes the speed signal and obtains the parameters applied in the testing of the fan 200, such as resistance, operation voltage and rotational speed. The parameters applied in the testing are then transmitted to the signal processing unit 113.

The signal processing unit 113 can process the testing parameters from the signal control unit 112, and generate corresponding test information for display on the display unit 114. In this embodiment, the display unit 114 can be a touch screen.

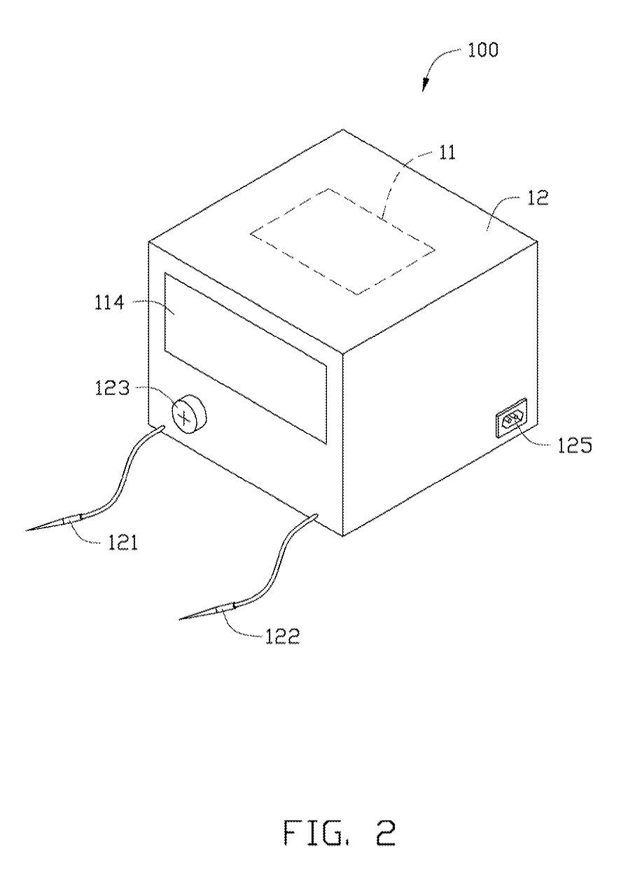

Referring to FIG. 2, the fan speed control device 100 further includes a housing 12 for receiving the speed regulating circuit 11, a first probe 121, a second probe 122, a rotating knob 123, and a power connector 125. The display unit 114 and the rotating knob 123 are located on one of the sidewalls of the housing 12, and the rotating knob 123 is mechanically connected to the sliding contact 116 to adjust and change the resistance of the adjustable resistor 111. For example, when the rotating knob 123 is rotated clockwise, the sliding contact 116 moves toward the fixed contact 115, and the resistance of the adjustable resistor 111 is decreased. When the rotating knob 123 is rotated counterclockwise, the sliding contact 116 moves away from the fixed contact 115, and the resistance of the adjustable resistor 111 is increased.

The first probe 121 is electrically connected to the sliding contact 116 through a wire, and the second probe 122 is electrically connected to the signal control unit 112. The first probe 121 and the second probe 122 can respectively contact the speed control signal port 203 and the speed signal port 204 of the fan 200 during testing. The power connector 125 is electrically connected to an external power source (e.g., the power supply unit 20) to power the speed regulating circuit 11.

In use, the power connector 125 is electrically connected to the power supply unit 20, and the first probe 121 and the second probe 122 are electrically connected to the speed control signal port 203 and the speed signal port 204 respectively. By turning the rotating knob 123, the resistance of the adjustable resistor 111 changes, so the operating voltage and current supplied to the fan 200 is varied accordingly. Thus, the rotational speed of the fan 200 may be adjusted by changing the operating voltage and current. The fan 200 transmits a speed signal to the signal control unit 112 via the speed signal port 204, and the signal control unit 112 obtains and transmits the testing parameters of the fan 200, such as operating voltage, resistance and rotational speed, to the signal processing unit 113. The signal processing unit 113 processes the parameters of the testing and generates test information to be displayed on the display unit 114.

In summary, in the fan speed control device 100 of the present disclosure, by operating the rotating knob 123, the resistance of the adjustable resistor 111 changes, and the operating voltage and current supplied to the fan 200 is varied accordingly. Thus, the rotational speed of the fan 200 can be adjusted in real-time and in small increments during testing, until the rotational speed of the fan 200 reaches a reference speed.

In the present specification and claims, the word “a” or “an” preceding an element does not exclude the presence of a plurality of such elements. Further, the word “comprising” does not exclude the presence of elements or steps other than those listed.

It is to be understood, however, that even though numerous characteristics and advantages of the exemplary disclosure have been set forth in the foregoing description, together with details of the structure and function of the exemplary disclosure, the disclosure is illustrative only, and changes may be made in detail, especially in the matters of shape, size, and arrangement of parts within the principles of this exemplary disclosure to the full extent indicated by the broad general meaning of the terms in which the appended claims are expressed.

What is claimed is:

1. A fan speed control device used for controlling rotational speed of a fan to test the performance of the fan, the fan comprising a speed control signal port and a speed signal port, the fan speed control device comprising:
a speed regulating circuit comprising:
a signal control unit electrically connected to the speed signal port of the fan; and
an adjustable resistor electrically connected between the signal control unit and the speed control signal port of the fan, wherein the resistance of the adjustable resistor is varied to change operating voltage and current supplied to the fan, and the rotational speed of the fan is adjusted according to the current operating voltage and current, and the signal control unit obtains speed signal from the speed signal port and processes current testing parameters of the fan.

2. The fan speed control device as claimed in claim 1, wherein the adjustable resistor comprises a fixed contact and a sliding contact, the fixed contact is electrically connected to the signal control unit, and the sliding contact is electrically connected to the speed control signal port of the fan and is moved towards or away from the fixed contact.

3. The fan speed control device as claimed in claim 2, wherein the signal control unit accepts signal as to the rotational speed from the speed signal port as input, processes the speed signal, to output the results of different operations performed in relation to the fan.

4. The fan speed control device as claimed in claim 3, wherein when the rotational speed of the fan changes, the fan sends the speed signal to the signal control unit through the speed signal port, the signal control unit processes the speed signal and obtains testing parameters of the fan according to the speed signal, the testing parameter comprises current resistance, operation voltage and rotational speed.

5. The fan speed control device as claimed in claim 4, wherein the speed regulating circuit further comprises a signal processing unit and a display unit, the signal processing unit and the display unit are electrically connected to the signal control unit, the signal processing unit receives and processes the testing parameters from the signal control unit, and generate corresponding test information for display on the display unit.

6. The fan speed control device as claimed in claim 5, wherein the display unit is a touch screen, the adjustable resistor is a potentiometer, variable resistor or rheostat.

7. The fan speed control device as claimed in claim 5, further comprising a housing and a rotating knob, wherein the speed regulating circuit is received in the housing, the display unit and the rotating knob are located on one of sidewalls of the housing, and the rotating knob is mechanically connected to the sliding contact to adjust and change the resistance of the adjustable resistor.

8. The fan speed control device as claimed in claim 7, further comprising a first probe, a second probe and a power connector, wherein the first probe is electrically connected to the sliding contact, and the second probe is electrically connected to the signal control unit, the first probe is electrically connected to the speed control signal port, and the second probe is electrically connected to the speed signal port, and the power connector is electrically connected to an external power source to power the fan speed control device.

9. A fan speed control device applied to a fan to control rotational speed of the fan to test the performance of the fan, the fan comprising a speed control signal port and a speed signal port, the fan speed control device comprising:
a signal control unit electrically connected to the speed signal port of the fan; and
an adjustable resistor electrically connected to the fan and the signal control unit, the adjustable resistor comprising:
a fixed contact electrically connected to the signal control unit; and
a sliding contact electrically connected to the speed control signal port of the fan, wherein the sliding contact is moved towards or away from relative to the fixed contact to vary the resistance of the adjustable resistor, voltage and current supplied to the fan is changed, the rotational speed of the fan is varied with the changes of the current operating voltage and current, and the signal control unit receives speed signal from the speed signal port and processes current testing parameters of the fan.

10. The fan speed control device as claimed in claim 9, wherein the signal control unit accepts speed signal from the speed signal port as input, processes the speed signal, and provides results as output to perform different operations.

11. The fan speed control device as claimed in claim 3, wherein when the rotational speed of the fan changes, the fan sends the speed signal to the signal control unit through the speed signal port, the signal control unit processes the speed signal and obtains testing parameters of the fan according to the speed signal, the testing parameter comprises current resistance, operation voltage and rotational speed.

12. The fan speed control device as claimed in claim 11, further comprising a signal processing unit and a display unit, wherein the signal processing unit and the display unit are electrically connected to the signal control unit, the signal processing unit receives and processes the testing parameters from the signal control unit, and generate corresponding test information that fits to be displayed on the display unit.

13. The fan speed control device as claimed in claim 12, wherein the display unit is a touch screen, the adjustable resistor is a potentiometer, variable resistor or rheostat.

14. The fan speed control device as claimed in claim 12, further comprising a housing and a rotating knob, wherein the adjustable resistor, the signal control unit, the signal processing unit and the display unit are received in the housing, the display unit and the rotating knob are located on one of sidewalls of the housing, and the rotating knob is mechanically connected to the sliding contact to adjust and change the resistance of the adjustable resistor.

15. The fan speed control device as claimed in claim 14, further comprising a first probe, a second probe and a power connector, wherein the first probe is electrically connected to the sliding contact, and the second probe is electrically connected to the signal control unit, the first probe is electrically connected to the speed control signal port, and the second probe is electrically connected to the speed signal port, and the power connector is electrically connected to an external power source to power the fan speed control device.
